(19) United States
(12) Patent Application Publication
(10) Pub. No.: US 2014/0251418 A1
(43) Pub. Date: Sep. 11, 2014

(54) TRANSPARENT CONDUCTIVE OXIDE LAYER WITH HIGH-TRANSMITTANCE STRUCTURES AND METHODS OF MAKING THE SAME

(71) Applicant: TSMC SOLAR LTD., Taichung City (TW)

(72) Inventor: Shih-Wei CHEN, Kaohsiung City (TW)

(73) Assignee: TSMC SOLAR LTD., Taichung City (TW)

(21) Appl. No.: 13/788,083

(22) Filed: Mar. 7, 2013

(51) Int. Cl. H01L 31/0224; H01L 31/0216

(52) U.S. Cl. CPC H01L 31/022466; H01L 31/02168
USPC 136/256; 438/98

(57) ABSTRACT

A solar cell with a transparent conductive layer having improved transmittance is described. The solar cell can include a solar cell substructure comprising an absorber layer disposed over a substrate; and a transparent conductive oxide (TCO) layer disposed over the substructure. The TCO layer can include a TCO film with a plurality of spaced-apart, high-transmittance structures therein. The TCO layer can have a higher transmittance of absorbable radiation than a comparable, homogeneous TCO film. The high-transmittance structures can be selected from the group consisting of perforations, high-transmittance particles, and combinations thereof. Methods of making solar cell with a transparent conductive layer having improved transmittance are also described.

### TECHNICAL FIELD

The disclosure relates to solar cells having transparent conductive oxide layers with high transmittance structures and methods of making the same.

### BACKGROUND

Solar cells are photovoltaic components for direct generation of electrical current from sunlight. Due to the growing demand for clean sources of energy, the manufacture of solar cells has expanded dramatically in recent years and continues to expand. Transparent conductive oxide, TCO, films are commonly used in solar cells due to their versatility as transparent coatings and also as electrodes. In order to provide both functions, TCO films are made from materials selected to exhibit a high transmittance of sunlight and a high conductivity (low resistivity). Previous methods and techniques for attempting to increase both transmittance and resistivity have not been wholly successful. In many cases, reducing resistance by adding dopants causes an undesirable decrease in transmittance.

### BRIEF DESCRIPTION OF THE DRAWING

The present disclosure is best understood from the following detailed description when read in conjunction with the accompanying drawing. It is emphasized that, according to common practice, the various features of the drawing are not necessarily to scale. On the contrary, the dimensions of the various features are arbitrarily expanded or reduced for clarity. Like numerals denote like features throughout the specification and drawing.

FIG. 1 is a cross-sectional view of a solar cell with a transparent conductive layer having a plurality of spaced-apart, high-transmittance structures therein.

FIG. 2 is a flow chart illustrating an embodiment of a method according to the disclosure.

FIG. 3 shows one embodiment for forming a solar cell with a transparent conductive layer having a plurality of spaced-apart, high-transmittance structures, with the A-series showing cross-sectional views and the B-series showing top views.

FIG. 4 shows a second embodiment for forming a solar cell with a transparent conductive layer having a plurality of spaced-apart, high-transmittance structures, with the A-series showing cross-sectional views and the B-series showing top views.

FIG. 5 shows a third embodiment for forming a solar cell with a transparent conductive layer having a plurality of spaced-apart, high-transmittance structures, with the A-series showing cross-sectional views and the B-series showing top views.

FIG. 6 is an SEM of a high-transmittance structure in a TCO film.

FIG. 7 is an absorption spectrum of the high-transmittance structure in a TCO film shown in FIG. 6.

### DETAILED DESCRIPTION

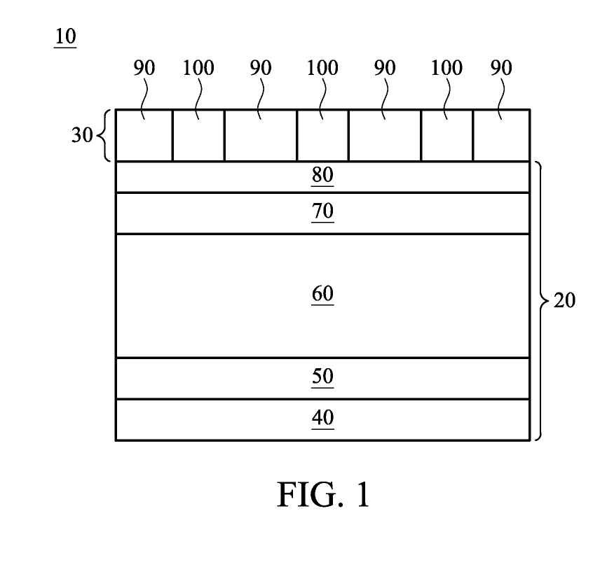

The disclosure provides for solar cells with transparent conductive oxide (TCO) layers that include spaced-apart, high-transmittance structures. The spaced-apart, high-transmittance structures 100 are separated from each other, and are not in direct contact with each other. Thus, by themselves, without the TCO film material, the spaced-apart, high-transmittance structures 100 form a discontinuous structure. The high-transmittance structures enable the TCO layer to utilize a TCO film with an increased conductivity (e.g., carrier density) while maintaining sufficient transmittance of absorbable radiation to produce an efficient solar cell. The disclosure also provides methods of forming the TCO layers described herein. A cross-sectional view of a solar cell incorporating a TCO layer that includes a plurality of spaced-apart, high-transmittance structures is provided in FIG. 1. Further details of the TCO layer and methods used to form the TCO layer are provided in conjunction with the subsequent figures.

In some embodiments, a solar cell 10 that includes a solar cell substructure 20 and a transparent conductive oxide (TCO) layer disposed 30 over the substructure 20 is described. The substructure 20 can include one or more of the following: a substrate 40, a reflective (back electrode) layer 50, an absorber layer 60, a buffer layer 70, and a protective coating 80. In some embodiments, the reflective layer 50 can be disposed over the substrate 40, the absorber layer 60 can be disposed over the reflective layer 50, the buffer layer 70 can be disposed over the absorber layer 60, and the protective coating 80 can be disposed over the buffer layer 70. The absorber layer 60 can be disposed over the substrate 40.

In some embodiments, the substructure 20 can include additional layers to meet design requirements of the particular solar cell. For example, additional buffer layers and barrier layers can be included between the substrate 40 and the absorber layer 60, between the absorber layer 60 and the TCO layer 30, or both. The layers described herein can be deposited using a variety of formation techniques, which include, but are not limited to, chemical vapor deposition, physical vapor deposition, and solvent techniques (e.g., chemical bath deposition).

The substrate 40 can be a glass substrate, such as soda lime glass, in some embodiments or any other suitable material in other embodiments. Other suitable materials include, but are not limited to, more flexible materials, such as, polyimides or metal foils.

The reflective layer 50 can function as a back contact for the solar cell and can reflect unabsorbed radiation back into the absorber layer 60. The reflective layer 50 can be molybdenum (e.g., deposited by sputtering) in some embodiments or any suitable material such as Pt, Au, Ag, Ni, or Cu, in other embodiments.

The absorber layer 60 can include one or more layer of absorbing films. The absorber layer 60 can include a copper indium gallium selenide (GIGS) film in some embodiments or any suitable film, such as CuInSe₂ (CIS), CuGaSe₂ (CGS), Cu(In,Ga)Se₂ (CIGS), Cu(In,Ga)(Se,S)₂ (CIGSS), CdTe or amorphous silicon, in other embodiments. The absorber layer 60 can include a p-type absorber film, e.g., a p-type CIGS film, in some embodiments.

The buffer layer 70 can be an n-type film in some embodiments or a p-type film in other embodiments. Where the absorber layer 60 includes a p-type film, the buffer layer 70 can be an n-type film. The buffer can be a CdS film in some embodiment or any suitable materials, such as ZnS In₂S₃, In2Se₃, or Zn₁₋ₓMgₓO, in other embodiments. The buffer layer 70 can be deposited by chemical bath deposition in some embodiments or any suitable technique in other embodiments.

The protective coating 80 can be disposed over the buffer layer 70. The protective coating 80 can be an intrinsic zinc oxide layer (i-ZnO) in some embodiments and any suitable material in other embodiments. The protective coating 80 can be helpful to prevent damage to the underlying substructure 40, 50, 60, 70, especially, when the subsequent layer, e.g., the TCO layer 30, is applied using sputtering.

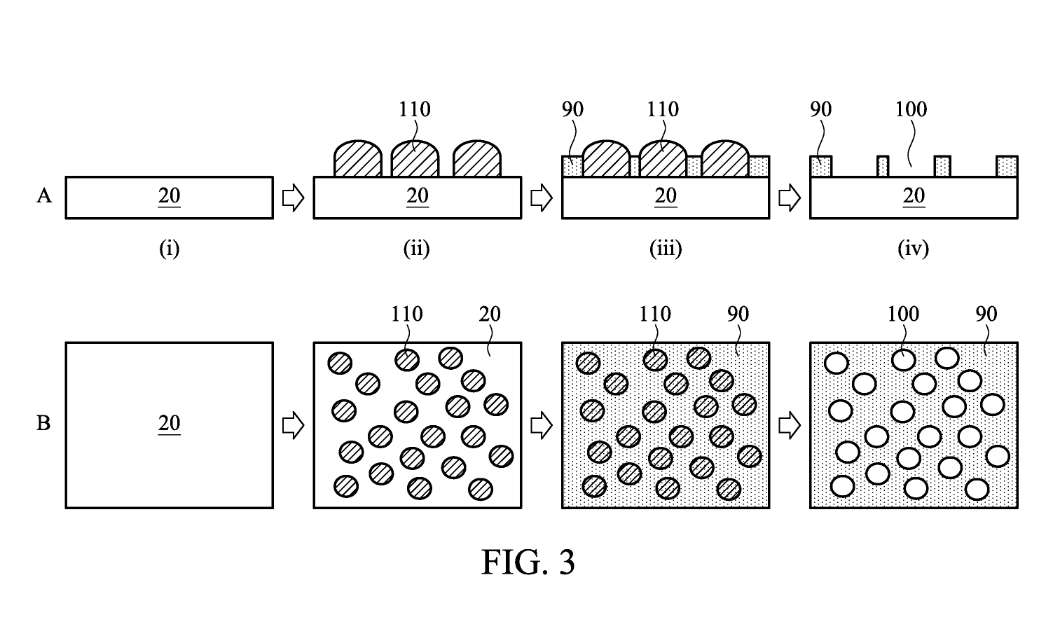

As best shown generally in FIGS. 3B(iv), 4B(iii) and 5B(iv), the TCO layer 30 can include a TCO film 90 with a plurality of spaced-apart, high-transmittance structures 100 therein. The TCO layer 30 can have a higher transmittance of absorbable radiation than a comparable, homogeneous TCO film. In some embodiments, the TCO film 90 can include a composition selected from the group consisting of aluminum-doped ZnO (AZO), gallium-doped ZnO (GZO), aluminum- and gallium-doped ZnO (AGZO), boron-doped ZnO (BZO), indium-doped CdO, indium tin oxide (ITO), fluorine-doped SnO (FTO), and combinations thereof. As used herein, “a comparable, homogeneous TCO film” refers to a TCO film formed on the same substructure using the same deposition technique that has the same composition as the TCO film 90 without the high transmittance structures 100.

As used herein, “absorbable radiation” refers generally to radiation absorbable by the absorber layer or layers of the solar cell. Absorbable radiation can include wavelengths ranging from 100 nm to 1000 nm or from 380 nm to 750 nm.

As used herein, “high-transmittance structures” refers to structures that have a transmittance for absorbable radiation that is greater than the TCO film 90. Examples of high-transmittance structures include, but are not limited to, particles and perforations (i.e., holes).

Thus, in some embodiments, a solar cell comprises a solar cell substructure comprising an absorber layer disposed over a substrate; and a transparent conductive oxide (TCO) layer disposed over the substructure, where the TCO layer comprises a TCO film with a plurality of separated, spaced-apart structures therein. The separated, spaced apart structures have a transmittance for absorbable radiation that is greater than the transmittance of the TCO film material.

In some embodiments, the high-transmittance structures 100 have a minimum cross-sectional dimension of at least 800 nm, or at least 1 micron, or at least 1.2 microns. In some embodiments, the size of the high-transmittance structures 100 is selected so that absorbable radiation can pass through the high-transmittance structures 100 to the underlying solar cell substructure 20. As used herein, “minimum cross-sectional dimension” refers to the minimum dimension in the plane of the TCO layer 30 (i.e., when viewed from above the TCO layer).

In some embodiments, the high-transmittance structures 100 have a maximum cross-sectional dimension of 100 microns or less, or 20 microns or less, or 10 microns or less. As used herein, “maximum cross-sectional dimension” refers to the maximum dimension in the plane of the TCO layer 30 (i.e., when viewed from above the TCO layer).

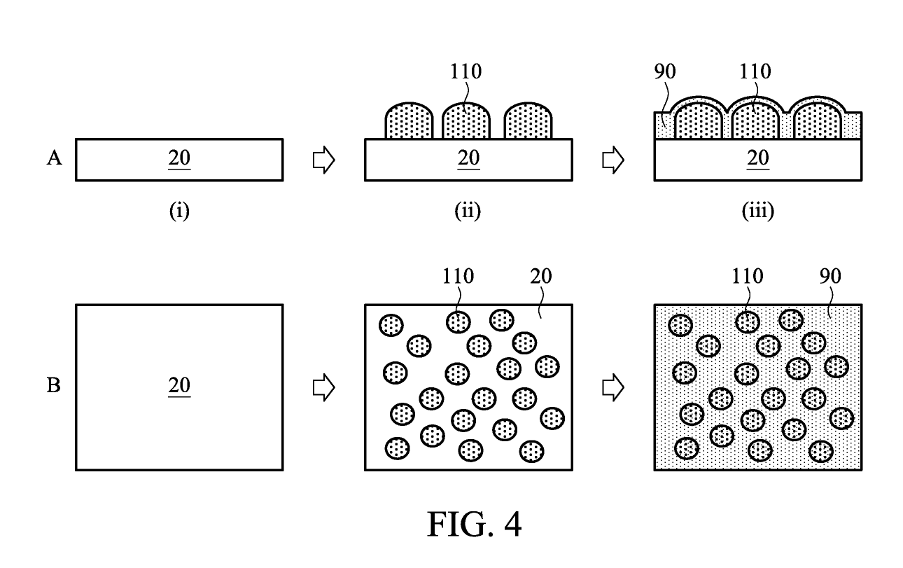

In some embodiments, the high-transmittance structures are selected from the group consisting of perforations, high-transmittance particles, and combinations thereof. In some embodiments, such as those shown in FIGS. 3 & 5, the high-transmittance structures 100 can pass all the way through the TCO film 90. In other embodiments, such as that shown in FIG. 4, the high-transmittance structures 100 can be embedded within the solar cell 10 and the TCO film 90 can extend over or under one or more of the high-transmittance structures 100.

In some embodiments, the TCO layer 30 can have a conductivity of at least 10³ S/cm, a conductivity of at least 5×10³ S/cm, or a conductivity of at least 10⁴ S/cm. In some embodiments, the carrier concentration in the TCO film 90 can be at least 10²⁰/cm³, at least 10²¹/cm³, or at least 10²²/cm³·7. In some embodiments, a resistivity of the TCO layer 30 can be 10⁻³ Ω·cm or less, 5×10⁻⁴ Ω·cm, or less or 10⁻⁴ Ω·cm or less.

In some embodiments, the transmittance of the TCO layer 30 is increased by at least 5% relative to a comparable, homogeneous TCO film. In other embodiments, the transmittance is increased at least 7.5% relative to a comparable, homogeneous TCO film. In still other embodiments, the transmittance is increased at least 5% compared to an comparable, homogeneous TCO film, or at least 7.5% compared to an comparable, homogeneous TCO film, or at least 10% compared to an comparable, homogeneous TCO film. As used herein, “compared to” is used to refer to an absolute difference, while “relative to” is used to refer to a percent increase relative to an initial value. For example, if the comparable, homogeneous TCO film has a transmittance of 80%, as 5% increase compared to 80% is 85%, while a 5% increase relative to 80% is 84%.

In another embodiment, the solar cell 10 can include a solar cell substructure 20, comprising an absorber layer 60 disposed on a substrate 40; and a transparent conductive oxide (TCO) layer 30 disposed over the solar cell substructure 20. The TCO layer 30 can include a TCO film 90 with a plurality of spaced-apart particles 100 therein. The particles 100 can have a minimum cross-sectional dimension of at least 800 nm and can be embedded in the TCO film 90. The TCO layer 30 can have a higher transmittance of absorbable radiation than a comparable, homogeneous TCO film.

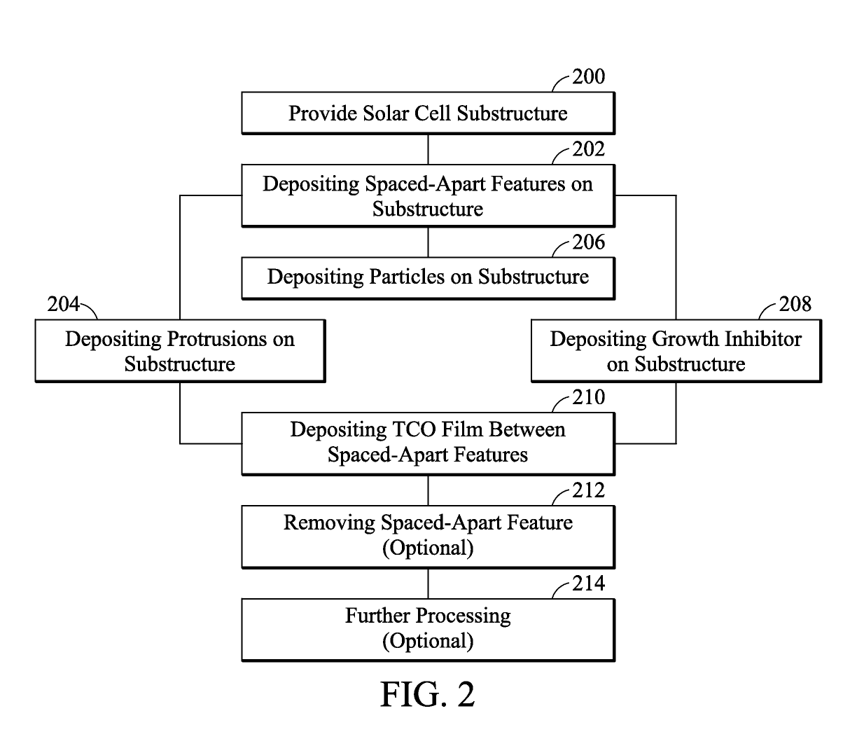

In accordance with some embodiments, FIG. 2 is a flowchart describing a broad method for carrying out the formation of a solar cell that includes a TCO layer 30 having a plurality of spaced-apart, high-transmittance structures 100. At step 200, a solar cell substructure 20 is provided. Additional details of the substructure 20 are described above with respect to FIG. 1. Step 202 provides for depositing spaced-apart features on the substructure 20. Step 202 can include depositing one or more protrusions 204, particles 206 or growth inhibitors 208. Step 210 provides for depositing the TCO film between the spaced apart features 110. Step 212, which is optional, provides for removing the spaced-apart features 110. Step 214, which is optional, provides for further processing, which can include, but is not limited to, chemical mechanical polishing, scribing, edge deletion, bonding, lamination and packaging.

Specific methods of forming the TCO layers 30 described herein are shown in FIGS. 3-5. The A and B series of FIGS. 3-5 show cross-sectional views and top plan views, respectively, of intermediate structures in processes for producing TCO layers 30 that include spaced-apart, high-transmittance structures 100.

FIG. 3(i) shows the solar cell substructure 20 as in step 200 of FIG. 2. FIG. 3(ii) shows the substructure 20 with a plurality of spaced-apart features 110 deposited over the substructure 20. The spaced-apart features 110 can be deposited on the substructure 20. The spaced-apart features 110 can be protrusions or particles. Where the spaced-apart features 110 are protrusions, the protrusions can be formed by a variety of techniques, which include, but are not limited to, chemical vapor deposition (CVD) technique or a physical vapor deposition (PVD) technique using masking techniques (such as lithography). Examples of CVD and PVD techniques include, but are not limited to, atmospheric pressure chemical vapor deposition (APCVD), atomic layer deposition (ALD), plasma enhanced chemical vapor deposition (PECVD), metal organic chemical vapor deposition (MOCVD), and sputtering.

Where the spaced-apart features 110 are particles, the particles can be deposited by using a solution technique in some embodiments and any suitable technique in other embodiments. For example, the technique can include forming a solution that includes the particles suspended in a solvent. In some embodiments, the solvent can be or can include ethanol or isopropanol, and can include any suitable solvent in other embodiments. The solution can also include one or more dispersing agents or other suitable ingredients. The solution can be applied to the substructure and the solvent can be removed, e.g. by evaporation.

FIG. 3(iii) shows the intermediate structure of FIG. 3(ii) after the TCO film 90 is deposited between the spaced-apart features 110. The TCO film 90 can be applied by a CVD technique or a PVD technique, which may be selective or non-selective. As shown in FIG. 3(iii), the TCO film 90 can cover the top of the spaced-apart features 110.

FIG. 3(iv) shows the intermediate structure of FIG. 3(iii) after the spaced-apart features 110 have been removed, as in Step 212 of FIG. 2. Where the spaced-apart features are being removed, as in the method of FIG. 3, the spaced-apart features can have a transmittance less than or equal to a transmittance of the TCO film. The spaces previously occupied by the spaced-apart features 110 now function as spaced-apart, high transmittance structures 100. In particular, the spaced-apart, high transmittance structures of FIG. 3(iv) can be perforations in some embodiments.

The spaced-apart features 110 can be removed by a variety of techniques, which include, but are not limited to, etching, vibrating (e.g., in a bath deionized water), or combinations thereof. In one embodiment, the spaced apart-features 110 can be particles that are removed using an ultrasonic bath in deionized water. In another embodiment, the spaced-apart features 110 can be protrusions that are removed by selective etching (e.g., by an acid).

FIG. 4 depicts another method for making the transparent conductive layer 30 with spaced-apart, high-transmittance structures. FIG. 4(i) shows the solar cell substructure 20 as in step 200 of FIG. 2. FIG. 4(ii) shows the substructure 20 with a plurality of spaced-apart features 110 deposited over the substructure 20. The spaced-apart features 110 can be deposited on the substructure 20, and can be protrusions or particles. The spaced-apart features 110 can have a transmittance of absorbable radiation that is greater than that of the TCO film 90.

As with FIG. 3, when the spaced-apart features 110 in FIG. 4(ii) are protrusions, the protrusions can be formed by a variety of techniques, which include, but are not limited to, chemical vapor deposition (CVD) technique or a physical vapor deposition (PVD) technique using masking techniques (such as lithography). As with FIG. 3, when the spaced-apart features 110 of FIG. 4(ii) are particles, the particles can be deposited by using a solution technique, such as that previously described.

FIG. 4(iii) shows the intermediate structure of FIG. 4(ii) after the TCO film 90 is deposited between the spaced-apart features 110. The TCO film 90 can be applied by a CVD technique or a PVD technique, which may be selective or non-selective. The TCO film 90 can be selectively deposited by a MOCVD process in some embodiments, or any other suitable process in other embodiments. As shown in FIG. 4(iii), the TCO film 90 can cover the top of the spaced-apart features 110 in some embodiments. In the embodiments of FIG. 4, the spaced-apart features 110 can also be spaced-apart, high transmittance structures 100. The TCO film 90 can be as thick or thicker than the spaced-apart structures 110 in some embodiments, while the spaced-apart structures 110 can extend above the TCO film 90 in other embodiments. In some embodiments, regardless of the relative thickness of the TCO film 90 and the spaced-apart structures 110, the TCO film does not cover the spaced-apart structures.

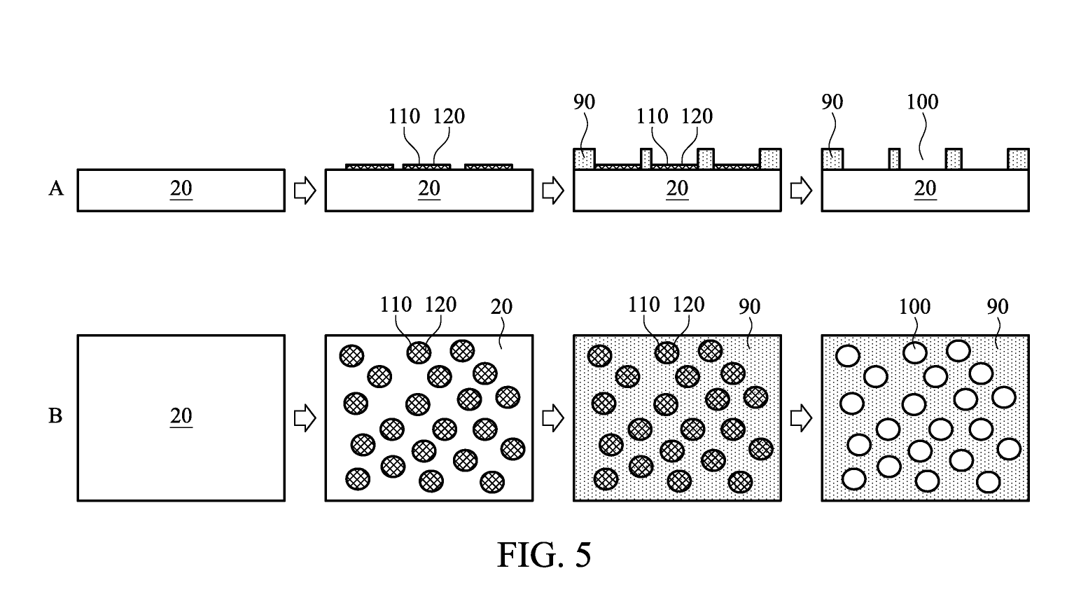

FIG. 5 depicts another method for making the transparent conductive layer 30 with spaced-apart, high-transmittance structures. FIG. 5(i) shows the solar cell substructure 20 as in step 200 of FIG. 2. FIG. 5(ii) shows the substructure 20 with a plurality of spaced-apart features 110 deposited over the substructure 20. The spaced-apart features 110 can be deposited on the substructure 20. The spaced-apart features 110 can be or can include a growth inhibitor 120. The growth inhibitor can be an acid or an alcohol (e.g., ethanol) in some embodiments and any suitable material in other embodiments (e.g., a coating). The growth inhibitor 120 can be applied by spraying (atomization) microdrops over or on the substructure 20.

FIG. 5(iii) shows the intermediate structure of FIG. 5(ii) after the TCO film 90 is deposited between the spaced-apart growth inhibitor 110/120. The TCO film 90 can be applied by a CVD technique or a PVD technique, which may be selectively deposited on the substructure 20 over the growth inhibitor 120.

FIG. 5(iv) shows the intermediate structure of FIG. 5(iii) after the spaced-apart features 110/120 have been removed, as in Step 212 of FIG. 2. The spaces previously occupied by and above the spaced-apart growth inhibitors 120 now function as spaced-apart, high transmittance structures 100. In particular, the spaced-apart, high transmittance structures 100 of FIG. 5(iv) can be perforations. The spaced-apart features 110 can be removed by a variety of techniques, which include, but are not limited to, rinsing, vibrating (e.g., in a bath of deionized water), or combinations thereof.

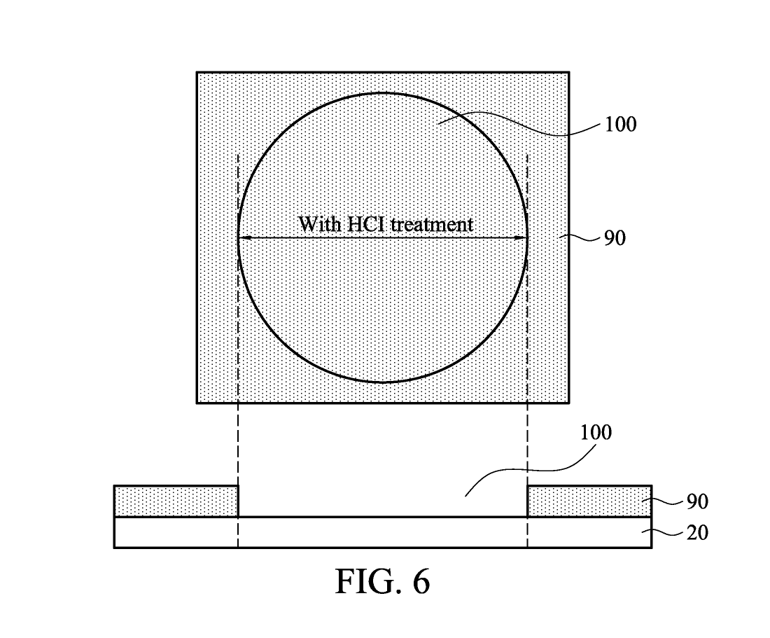

FIG. 6 shown an SEM image of an individual spaced-apart, high-transmittance structure 100 with a schematic cross-section of the structure below. The spaced-apart, high-transmittance structure 100 in FIG. 6 was formed using a drop of HCl as a growth inhibitor followed by selective deposition of a TCO film 90 formed from a boron-doped ZnO (BZO). Both the TCO film 90 and the underlying CIGS substructure 20 were 1,500 μm thick and the diameter of the high-transmittance structure was 200 μm.

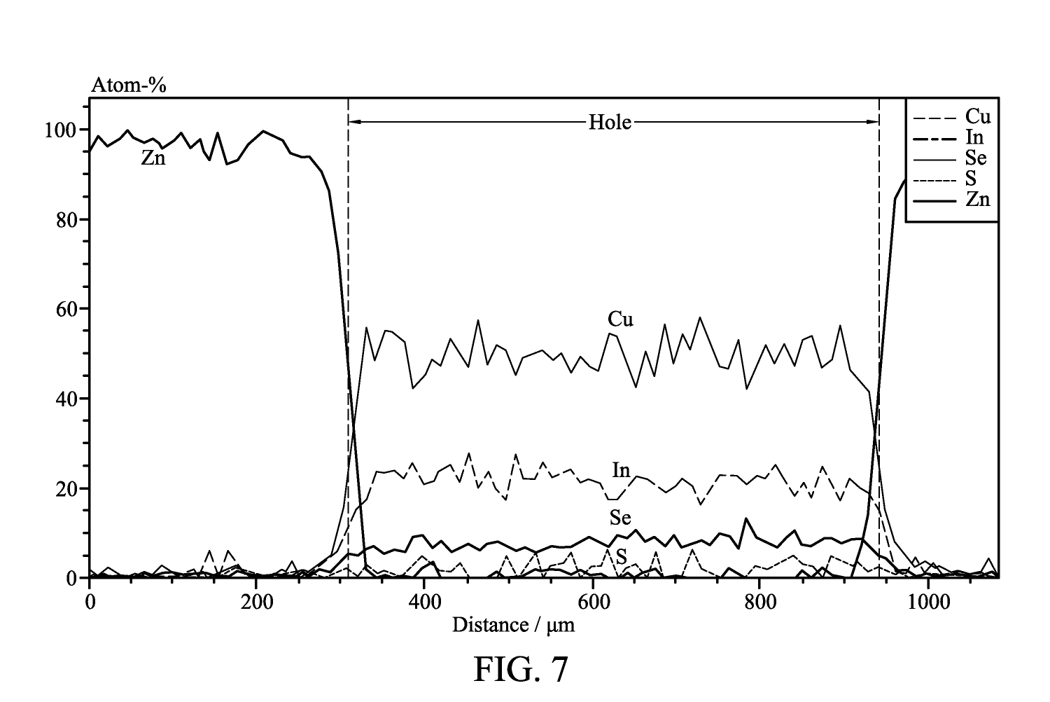

FIG. 7 is an absorption spectrum across the width of the spaced-apart, high-transmittance structure 100 of FIG. 6. As is evident from the scan, the copper, selenium, Indium and sulfur signals are significant within the spaced-apart, high-transmittance structure 100, while they are suppressed by the zinc signal where the TCO film 90 is present. This data confirms the efficacy of the strategy of the TCO layers 30 described herein.

In some embodiments, a solar cell is provided. The solar cell can include a solar cell substructure comprising an absorber layer disposed over a substrate; and a transparent conductive oxide (TCO) layer disposed over the substructure. The TCO layer includes a TCO film with a plurality of separated spaced-apart structures therein. The separated spaced-apart structures have a higher transmittance of absorbable radiation than the TCO film.

In some embodiments, the TCO film comprises a composition selected from the group consisting of aluminum-doped ZnO, gallium-doped ZnO, aluminum- and gallium-doped ZnO, boron-doped ZnO, indium-doped CdO, indium tin oxide, fluorine-doped SnO, and combinations thereof.

In some embodiments, the separated spaced-apart structures have a minimum cross-sectional dimension of at least 800 nm.

In some embodiments, the separated spaced-apart structures have a maximum cross-sectional dimension of 100 microns or less in diameter.

In some embodiments, the separated spaced-apart structures are selected from the group consisting of perforations, high-transmittance particles, and combinations thereof.

In some embodiments, a conductivity of the TCO layer is at least 10³ S/cm. In some embodiments, a resistivity of said TCO layer is 10⁻³ Ω·cm or less.

In some embodiments, a transmittance of said TCO layer is increased by at least 5% relative to a comparable, homogeneous TCO film.

In some embodiments, a solar cell is provided. The solar cell includes a solar cell substructure, comprising an absorber layer disposed on a substrate; and a transparent conductive oxide (TCO) layer disposed over the solar cell substructure. The TCO layer includes a TCO film with a plurality of spaced-apart, particles therein. The particles have a minimum cross-sectional dimension of at least 800 nm and are embedded in the TCO film. The TCO layer has a higher transmittance of absorbable radiation than a comparable, homogeneous TCO film.

In some embodiments, a method of forming a solar cell is provides. The method can include providing a solar cell substructure comprising an absorber layer disposed over a substrate; and forming a transparent conductive oxide (TCO) layer disposed over the substructure. The TCO layer includes a TCO film with a plurality of spaced-apart, high-transmittance structures therein, and the TCO layer has a higher transmittance of absorbable radiation than a comparable, homogeneous TCO film.

In some embodiments, a transmittance of the TCO layer is increased by at least 5% relative to a comparable, homogeneous TCO film.

In some embodiments, forming the TCO layer comprises: (i) depositing a plurality of spaced-apart features over the substructure, and depositing the TCO film between the spaced-apart features.

In some embodiments, the space-apart features are selected from the group consisting of particles, protrusions, growth inhibitors, and combinations thereof.

In some embodiments, the method also includes removing the spaced-apart features.

In some embodiments, the spaced-apart features comprise a growth inhibitor. In some embodiments, the growth inhibitor comprises a liquid.

In some embodiments, the spaced-apart features comprise particles with a transmittance greater than a transmittance of the TCO film.

In some embodiments, the spaced-apart features comprise particles or protrusions with a transmittance less or equal to a transmittance of the TCO film.

In some embodiments, the spaced-apart features are particles, and depositing the plurality of spaced-apart features comprises: (i) forming a solution comprising the particles suspended in a solvent, (ii) applying the solution over the substructure, and (iii) removing the solvent.

In some embodiments, the spaced-apart features are protrusions and the method further comprises removing the protrusions by etching.

In some embodiments, the spaced-apart, high-transmittance structures are selected from the group consisting of particles, perforations, and combinations thereof.

The preceding merely illustrates the principles of the disclosure. It will thus be appreciated that those of ordinary skill in the art will be able to devise various arrangements which, although not explicitly described or shown herein, embody the principles of the disclosure and are included within its spirit and scope. Furthermore, all examples and conditional language recited herein are principally intended expressly to be only for pedagogical purposes and to aid the reader in understanding the principles of the disclosure and the concepts contributed by the inventors to furthering the art, and are to be construed as being without limitation to such specifically recited examples and conditions. Moreover, all statements herein reciting principles, aspects, and embodiments of the disclosure, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure.

This description of the exemplary embodiments is intended to be read in connection with the figures of the accompanying drawing, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Although the disclosure has been described in terms of exemplary embodiments, it is not limited thereto. Rather, the appended claims should be construed broadly, to include other variants and embodiments of the disclosure, which may be made by those of ordinary skill in the art without departing from the scope and range of equivalents of the disclosure.

What is claimed is:

1. A solar cell comprising:
a solar cell substructure comprising an absorber layer disposed over a substrate; and
a transparent conductive oxide (TCO) layer disposed over said substructure, wherein said TCO layer comprises a TCO film with a plurality of separated spaced-apart, structures therein, and wherein said separated spaced-apart structures have a higher transmittance of absorbable radiation than the TCO film.

2. The solar cell as in claim 1, wherein said TCO film comprises a composition selected from the group consisting of aluminum-doped ZnO, gallium-doped ZnO, aluminum- and gallium-doped ZnO, boron-doped ZnO, indium-doped CdO, indium tin oxide, fluorine-doped SnO, and combinations thereof.

3. The solar cell as in claim 1, wherein said separated spaced-apart structures have a minimum cross-sectional dimension of at least 800 nm.

4. The solar cell as in claim 1, wherein said separated spaced-apart structures have a maximum cross-sectional dimension of 100 microns or less.

5. The solar cell as in claim 1, wherein said separated spaced-apart structures comprise at least one of perforations and high-transmittance particles.

6. The solar cell as in claim 1, wherein a conductivity of said TCO layer is at least 5×10³ S/cm.

7. The solar cell as in claim 1, wherein a resistivity of said TCO layer is 5×10⁻⁴ Ω·cm or less.

8. The solar cell as in claim 1, wherein a transmittance of said TCO layer is increased by at least 5% relative to a comparable, homogeneous TCO film.

9. A solar cell comprising:
a solar cell substructure, comprising an absorber layer disposed on a substrate; and
a transparent conductive oxide (TCO) layer disposed over said solar cell substructure, wherein said TCO layer comprises a TCO film with a plurality of spaced-apart, particles therein, wherein said particles have a minimum cross-sectional dimension of at least 800 nm and are embedded in said TCO film, and wherein said TCO layer has a higher transmittance of absorbable radiation than a comparable, homogeneous TCO film.

10. A method for forming a solar cell, comprising:
providing a solar cell substructure comprising an absorber layer disposed over a substrate; and
forming a transparent conductive oxide (TCO) layer disposed over said substructure, wherein said TCO layer comprises a TCO film with a plurality of spaced-apart, high-transmittance structures therein, and wherein said TCO layer has a higher transmittance of absorbable radiation than a comparable, homogeneous TCO film.

11. The method as in claim 10, wherein a transmittance of said TCO layer is increased by at least 5% relative to a comparable, homogeneous TCO film.

12. The method as in claim 10, wherein forming said TCO layer comprises:
depositing a plurality of spaced-apart features over said substructure, and
depositing said TCO film between said spaced-apart features.

13. The method as in claim 12, wherein said space-apart features are selected from the group consisting of particles, protrusions, growth inhibitors, and combinations thereof.

14. The method as in claim 12, further comprising removing said spaced-apart features.

15. The method as in claim 12, wherein said spaced-apart features comprise a growth inhibitor, and said depositing said TCO fim comprises growing said TCO film in an MOCVD process.

16. The method as in claim 12, wherein said spaced-apart features comprise particles with a transmittance greater than a transmittance of said TCO film.

17. The method as in claim 12, wherein said spaced-apart features comprise particles or protrusions with a transmittance less than a transmittance of said TCO film.

18. The method as in claim 12, wherein said spaced-apart features are particles, and depositing said plurality of spaced-apart features comprises:
forming a solution comprising said particles suspended in a solvent,
applying said solution over said substructure, and
removing said solvent.

19. The method as in claim 10, wherein said spaced-apart features are protrusions and said method further comprises removing said protrusions by etching.

20. The method as in claim 10, wherein said spaced-apart, high-transmittance structures are selected from the group consisting of particles, perforations, and combinations thereof.
